(19) United States
(12) Patent Application Publication
(10) Pub. No.: US 2024/0058839 A1
(43) Pub. Date: Feb. 22, 2024

(54) VACUUM TREATMENT APPARATUS AND VACUUM TREATMENT METHOD

(71) Applicant: ULVAC, INC., Chigasaki-shi (JP)

(72) Inventors: Shunsuke SASAKI, Chigasaki-shi (JP); Takahito KIMOTO, Chigasaki-shi (JP); Yoshiaki FUKUDA, Chigasaki-shi (JP); Ken MAEHIRA, Chigasaki-shi (JP)

(21) Appl. No.: 18/360,950

(22) Filed: Jul. 28, 2023

(30) Foreign Application Priority Data
Aug. 19, 2022 (JP) 2022-130962

(51) Int. Cl. B05D 1/28

(52) U.S. Cl. CPC B05D 1/28

(57) ABSTRACT

A vacuum treatment apparatus including: a first wind-off roller paying out a first base material; a first wind roller winding the first base material; a main roller having an outer circumferential surface in contact with a non-film deposition surface, and winding and conveying the first base material, at least a part of the outer circumferential surface, which is uncovered with the first base material, being coated with an insulating material; a deposition source facing the outer circumferential surface of the main roller; a second wind-off roller paying out a second base material that is wound and conveyed by the main roller and covers a part of a film deposition surface of the first base material on the outer circumferential surface of the main roller; a second wind roller winding the second base material; and a power source applying a bias potential to the main roller.

### CROSS REFERENCE TO RELATED APPLICATIONS

This application claims the benefit of Japanese Priority Patent Application JP 2022-130962 filed Aug. 19, 2022, the entire contents of which are incorporated herein by reference.

### BACKGROUND

The present invention relates to a vacuum treatment apparatus and a vacuum treatment method.

There is known a film deposition system using roll-to-roll processing that forms a film on an elongated film deposition target base material (band-like film) while winding the base material through a main roller in a pressure-reduced atmosphere. In such a film deposition system, a deposition source is disposed facing the film deposition target base material wound and conveyed by the main roller for depositing a film deposition material fed from the deposition source on the film deposition target base material (e.g., see Japanese Patent Application Laid-open No. 2009-019246 (hereinafter, referred to as Patent Literature 1)). Accordingly, the film is formed on the film deposition target base material wound and conveyed by the main roller.

### SUMMARY

The above-mentioned film deposition system in some cases winds and conveys the film deposition target base material and a masking base material for covering a part of base material for the film deposition through the main roller and deposits the film deposition material on a predetermined portion of the film deposition target base material.

However, in those cases, an electrical short-circuit where electric charges with which the masking base material is charged due to electrostatic charging flow down to the main roller can occur when the masking base material is peeled off from the film deposition target base material. In a case of performing film deposition while applying a bias potential on the main roller, such a short-circuit can make the bias potential unstable during film deposition.

In view of the above-mentioned circumstances, it is desirable to provide a vacuum treatment apparatus and a vacuum treatment method that are capable of stably applying a bias potential to a main roller during film deposition.

According to an embodiment of the present invention, a vacuum treatment apparatus includes a first wind-off roller, a first wind roller, a main roller, a deposition source, a second wind-off roller, a second wind roller, and a power source.

The first wind-off roller pays out a first base material having a film deposition surface and a non-film deposition surface opposite to the film deposition surface.

The first wind roller winds the first base material.

The main roller is provided between the first wind-off roller and the first wind roller in a direction in which the first base material is conveyed, has an outer circumferential surface that is held in contact with the non-film deposition surface, and winds and conveys the first base material, at least a part of the outer circumferential surface, which is uncovered with the first base material, being coated with an insulating material.

The deposition source faces the outer circumferential surface of the main roller that is held in contact with the non-film deposition surface.

The second wind-off roller pays out a second base material that is wound and conveyed by the main roller and covers a part of the film deposition surface of the first base material on the outer circumferential surface of the main roller.

The second wind roller winds the second base material.

The power source applies a bias potential to the main roller.

In accordance with such a vacuum treatment apparatus, the bias potential can be stably applied to the main roller during film deposition.

In the vacuum treatment apparatus, the main roller may have both end portions coated with the insulating material.

In accordance with such a vacuum treatment apparatus, the bias potential can be stably applied to the main roller during film deposition.

In the vacuum treatment apparatus, the second base material may be wound and conveyed by the main roller while the second base material is held in contact with the insulating material on the outer circumferential surface of the main roller.

In accordance with such a vacuum treatment apparatus, the bias potential can be stably applied to the main roller during film deposition.

According to an embodiment of the present invention, a vacuum treatment method includes by use of
a first wind-off roller that pays out a first base material having a film deposition surface and a non-film deposition surface opposite to the film deposition surface,
a first wind roller that winds the first base material,
a main roller that is provided between the first wind-off roller and the first wind roller in a direction in which the first base material is conveyed, has an outer circumferential surface that is held in contact with the non-film deposition surface, and winds and conveys the first base material, at least a part of the outer circumferential surface, which is uncovered with the first base material, being coated with an insulating material,
a deposition source that faces the outer circumferential surface of the main roller that is held in contact with the non-film deposition surface,
a second wind-off roller that pays out a second base material that is wound and conveyed by the main roller and covers a part of the film deposition surface of the first base material on the outer circumferential surface of the main roller, and
a second wind roller that winds the second base material,
forming a film deposition material on the film deposition surface while applying a bias potential to the main roller.

In accordance with such a vacuum treatment method, the bias potential can be stably applied to the main roller during film deposition.

In the vacuum treatment method, both end portion of the main roller may be coated with the insulating material.

In accordance with such a vacuum treatment method, the bias potential can be stably applied to the main roller during film deposition.

In the vacuum treatment method, the second base material may be wound and conveyed by the main roller while the second base material is held in contact with the insulating material on the outer circumferential surface of the main roller.

In accordance with such a vacuum treatment method, the bias potential can be stably applied to the main roller during film deposition.

As described above, in accordance with the present invention, a vacuum treatment apparatus and a vacuum treatment method that are capable of stably applying a bias potential to a main roller during film deposition is provided.

### BRIEF DESCRIPTION OF DRAWINGS

FIG. 1 is a schematic diagram showing an example of a vacuum treatment apparatus according to the present embodiment;

FIGS. 2(a)-2(c) are cross-sectional views schematically showing an example of a vacuum treatment method according to the present embodiment;

FIGS. 3(a)-3(c) are diagrams describing actions of a vacuum treatment apparatus according to a comparative example; and

FIGS. 4(a) and 4(b) are diagrams describing actions of the vacuum treatment apparatus according to the present embodiment.

### DETAILED DESCRIPTION OF EMBODIMENTS

Hereinafter, embodiments of the present invention will be described with reference to the drawings. XYZ-axis coordinates are used in some figures of the drawings. Moreover, the same components or components having the same functions will be sometimes denoted by the same reference signs and duplicated descriptions of the components will be sometimes omitted as appropriate. In addition, numeric values described below are exemplary and not limitative.

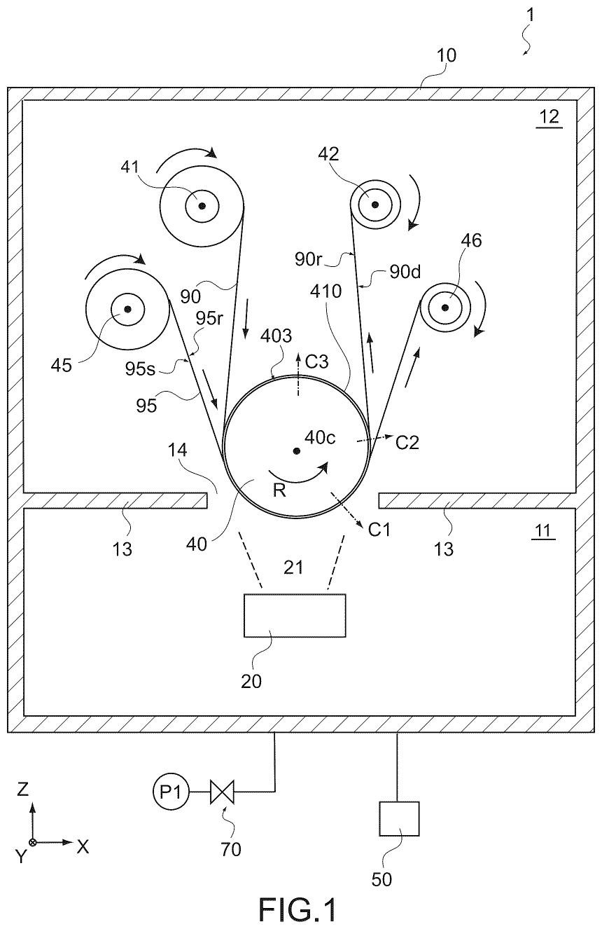

FIG. 1 is a schematic diagram showing an example of a vacuum treatment apparatus according to the present embodiment. A vacuum treatment apparatus 1 illustrated in FIG. 1 is a vacuum treatment apparatus using roll-to-roll processing that forms a film on an elongated base material 90 under a condition of a pressure-reduced atmosphere below an atmospheric pressure. In FIG. 1, a direction of a center axis 40c of a main roller 40 is a Y-axis direction and a direction from a deposition source 20 to the main roller 40 is a Z-axis direction. A direction orthogonal to the Y-axis direction and the Z-axis direction is an X-axis direction.

The vacuum treatment apparatus 1 includes a vacuum chamber 10, the deposition source 20, the main roller 40, a wind-off roller 41 (first wind-off roller), a wind roller 42 (first wind roller), a wind-off roller 45 (second wind-off roller), a wind roller 46 (second wind roller), a bias power source 50, and a gas discharge mechanism 70. A guide roller (not shown) for guiding the base material 90 (first base material) may be provided between the main roller 40 and the wind-off roller 41 or between the main roller 40 and the wind roller 42. A guide roller (not shown) for guiding a base material 95 (second base material) may be provided between the main roller 40 and the wind-off roller 45 or between the main roller 40 and the wind roller 46. The vacuum treatment apparatus 1 includes a rotational driving mechanism (not shown) for rotating each of the main roller 40, the wind-off roller 41, the wind roller 42, the wind-off roller 45, the wind roller 46, and the guide roller. Moreover, the vacuum treatment apparatus 1 may include a gas feeding mechanism for feeding a gas into the vacuum chamber 10.

In the vacuum treatment apparatus 1, the base material 90 is a base material for film deposition and is conveyed to the main roller 40 from the wind-off roller 41 and to the wind roller 42 from the main roller 40 at a predetermined conveying velocity inside the vacuum chamber 10. For example, the base material 90 is wound by the wind-off roller 41 and paid out to the main roller 40 from the wind-off roller 41. The base material 90 paid out to the main roller 40 from the wind-off roller 41 is wound and conveyed by the main roller 40 and is wound by the wind roller 42. A film deposition material fed from the deposition source 20 is deposited on the base material 90 wound and conveyed by the main roller 40 and a film is formed on the base material 90.

The base material 95 is a masking base material for covering the base material 90. The base material 95 is conveyed at a predetermined conveying velocity inside the vacuum chamber 10 to the main roller 40 from the wind-off roller 45 and to the wind roller 46 from the main roller 40. For example, the base material 95 is wound by the wind-off roller 45 and is paid out to the main roller 40 from the wind-off roller 45. The base material 95 paid out to the main roller 40 from the wind-off roller 45 is wound and conveyed by the main roller 40 while covering a part of the base material 90 wound and conveyed by the main roller 40 and is wound by the wind roller 46.

The vacuum chamber 10 has a hermetically-sealed structure. The vacuum chamber 10 can be kept in a predetermined pressure-reduced atmosphere through the gas discharge mechanism 70 with the vacuum pump P1. The vacuum treatment apparatus 1 includes, for example, a film deposition chamber 11 and a treatment chamber 12. The film deposition chamber 11 and the treatment chamber 12 are partitioned by a partition wall 13. The vacuum chamber 10 houses the deposition source 20, the main roller 40, the wind-off roller 41, the wind roller 42, the wind-off roller 45, and the wind roller 46 in the example in FIG. 1.

The partition wall 13 has an opening 14 so that a part of the main roller 40 can enter the film deposition chamber 11 from the treatment chamber 12 without contact between the main roller 40 and the partition wall 13. Moreover, the presence of the opening 14 in the partition wall 13 makes a clearance between the main roller 40 and the partition wall 13. The base materials 90 and 95 wound and conveyed by the main roller 40 pass between the treatment chamber 12 and the film deposition chamber 11 through this clearance.

The deposition source 20 is provided in the film deposition chamber 11. The deposition source 20 includes an evaporation source, for example. The deposition source 20 faces an outer circumferential surface 403 of the main roller 40. The deposition source 20 includes a resistance heating evaporation source, an induction heating evaporation source, an electron-beam heating evaporation source, and other evaporation sources. A film deposition material, e.g., an alkaline metal or alkaline earth metal is evaporated toward the main roller 40 from the deposition source 20. The film deposition material includes alkaline metals such as Li and Na and alkaline earth metals such as Mg and Ca, for example. A film formed on the base material 90 has a thickness of 20 μm or less. When a Li film is used as the film, this film is used for a negative electrode of a lithium battery, for example.

The film deposition chamber 11 is connected to the gas discharge mechanism 70. The film deposition chamber 11 maintains a reduced-pressure state through the gas discharge mechanism 70. The treatment chamber 12 is in communication with the film deposition chamber 11 through the opening 14. The treatment chamber 12 is evacuated through the opening 14 when the film deposition chamber 11 is evacuated. In the example in FIG. 1, the treatment chamber 12 is not connected to the gas discharge mechanism 70. Accordingly, a pressure difference is generated where the pressure of the treatment chamber 12 is higher than the pressure of the film deposition chamber 11 when the film deposition chamber 11 is evacuated. This pressure difference inhibits a vapor flow 21 (film deposition material) from the deposition source 20 from entering the treatment chamber 12 through the opening 14. It should be noted that the treatment chamber 12 is evacuated through the gas discharge mechanism depending on needs.

The main roller 40 is provided between the wind-off roller 41 and the wind roller 42 in a direction in which the base material 90 is conveyed (direction along the direction of the conveyed base material 90). A part of the main roller 40 is arranged in the film deposition chamber 11 and the other part is arranged in the treatment chamber 12. The main roller 40 faces the deposition source 20. The main roller 40 has the outer circumferential surface 403 that is held in contact with a non-film deposition surface (back surface) 90r of the base material 90. In the example in FIG. 1, the main roller 40 rotates counter-clockwise. In the present embodiment, the direction in which the main roller 40 rotates will be referred to as a direction of rotation R.

The main roller 40 contains a metal material such as stainless steel, iron, and aluminum and has a tubular shape. For example, a temperature control mechanism (not shown) may be provided inside the main roller 40. A width of the main roller 40 in the direction of the center axis 40c is set to be larger than a width of the base material 90. The main roller 40 winds and conveys the base material 90 unwound by the wind-off roller 41 and pays out the base material 90 with the film formed thereon toward the wind roller 42.

At least a part of the outer circumferential surface 403 of the main roller 40 is coated with an insulating material 410 in the form of a layer. The insulating material 410 is provided surrounding the main roller 40 along the outer circumferential surface 403. For example, at least a part of the outer circumferential surface 403, which is uncovered with the base material 90, is coated with the insulating material 410 when the main roller 40 winds and conveys the base material 90. The insulating material 410 has a thickness of, for example, 10 μm or more and 100 μm or less. If the insulating material 410 has a thickness smaller than 10 μm, it deteriorates insulation of the insulating material 410, so it is unfavorable. If the insulating material 410 has a thickness larger than 100 μm, a step of the base material 90 in contact with the insulating material 410 on the main roller 40 is thicker, so it is unfavorable.

Examples of the material of the insulating material 410 include an oriented polypropylene (OPP) resin, a polyethylene terephthalate (PET) resin, a polyphenylene sulfide (PPS) resin, and a polyimide (PI) resin.

The wind-off roller 41 is provided in the treatment chamber 12. The base material 90 is wound around the wind-off roller 41 in advance. The wind-off roller 41 rotates around its center axis in the arrow direction at a predetermined rotation velocity. The wind-off roller 41 pays out the base material 90 toward the main roller 40.

The wind roller 42 is provided in the treatment chamber 12. The wind roller 42 rotates around its center axis in the arrow direction at a predetermined rotation velocity. The wind roller 42 winds the base material 90 wound and conveyed by the main roller 40 and has the film deposition material deposited thereon.

The wind-off roller 45 is provided in the treatment chamber 12. The base material 95 is wound around the wind-off roller 45 in advance. the wind-off roller 45 rotates around its center axis in the arrow direction at a predetermined rotation velocity. The wind-off roller 45 pays out the base material 95 toward the main roller 40.

The wind roller 46 is provided in the treatment chamber 12. The wind roller 46 rotates around its center axis in the arrow direction at a predetermined rotation velocity. The wind roller 46 winds the base material 95 after the base material 95 covering the part of the base material 90 on the main roller 40 is peeled off from the base material 90.

The base material 90 includes a film deposition surface 90d and a non-film deposition surface 90r opposite to the film deposition surface 90d. The film deposition surface 90d faces the deposition source 20. The vapor flow 21 fed from the deposition source 20 is deposited on the film deposition surface 90d and a film is formed on the film deposition surface 90d of the base material 90 on the main roller 40. The non-film deposition surface 90r is held in contact with the outer circumferential surface 403 of the main roller 40.

The base material 90 is a sheet-like elongated film (with a thickness of 50 μm or less). The base material 90 is flexible. For example, the base material 90 is a band-like film constituted by an oriented polypropylene (OPP) resin, a polyethylene terephthalate (PET) resin, a polyphenylene sulfide (PPS) resin, and/or a polyimide (PI) resin. The base material 90 may be a band-like metal foil constituted by Cu, Al, Ni, and/or SUS steel, for example.

The base material 95 includes a covering surface 95r that covers a part of the film deposition surface 90d and a non-covering surface 95s opposite to the covering surface 95r. The base material 95 covers the part of the film deposition surface 90d of the base material 90 on the outer circumferential surface 403 of the main roller 40. The non-covering surface 95s of the base material 95 faces the deposition source 20. The base material 95 covering the part of the film deposition surface 90d of the base material 90 causes a film to be formed in a predetermined portion of the film deposition surface 90d of the base material 90 on the main roller 40.

The base material 95 is a sheet-like elongated film (with a thickness of 50 μm or less). The base material 95 is flexible. For example, the base material 95 is a band-like film constituted by an oriented polypropylene (OPP) resin, a polyethylene terephthalate (PET) resin, a polyphenylene sulfide (PPS) resin, and/or a polyimide (PI) resin.

The bias power source 50 is provided outside the vacuum chamber 10. The bias power source 50 applies a bias potential (e.g., a positive potential) to the main roller 40. Applying the bias potential to the main roller 40 causes an electrostatic force to act between the base material 90 and the main roller or between the base material 95 and the main roller. Accordingly, an electrostatic adhesion force acts between the main roller 40 and the base materials 90 and 95 when the main roller 40 winds and conveys the base materials 90 and 95, and it suppresses deviation and wrinkling of the base material 90 and the base material 95 on the main roller 40. It should be noted that the vacuum chamber 10, the wind-off roller 41, the wind roller 42, the wind-off roller 45, and the wind roller 46 are set at a ground potential.

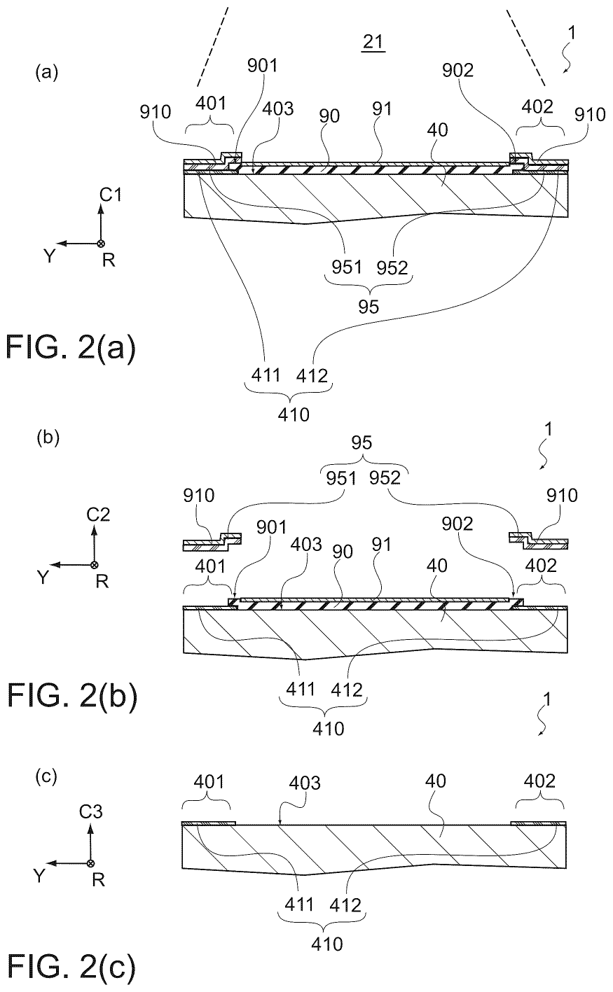

An operation of depositing the film deposition material from the deposition source 20 on the film deposition surface 90d of the base material 90 by the use of the vacuum treatment apparatus 1 will be described. FIG. 2(a) to FIG. 2(c) are cross-sectional views schematically showing an example of the vacuum treatment method according to the present embodiment.

FIG. 2(a) schematically shows cross-sections of the respective base materials, the film, the insulating material, and the main roller taken along the long dashed short dashed line C1 shown in FIG. 1.

As shown in FIG. 2(a), both end portions (end portions 401 and 402) of the main roller 40 are coated with the insulating material 410. The insulating material 410 is, for example, divided into two parts, includes an insulating material 411 and an insulating material 412. For example, the one end portion 401 of the main roller 40 is coated with the insulating material 411 and the other end portion 402 of the main roller 40 is coated with the insulating material 412. At the position of the long dashed short dashed line C1, the base material 90 is wound and conveyed by the main roller 40, one end portion 901 of the base material 90 is located on the insulating material 411, and the other end portion 902 of the base material 90 is located on the insulating material 412.

Moreover, at the position of the long dashed short dashed line C1, the base material 95 for masking is wound and conveyed by the main roller 40, held in contact with the insulating material 410 on the outer circumferential surface 403 of the main roller 40. The base material 95 is constituted by two elongated base materials, for example, and includes a base material 951 and a base material 952, for example. The base material 951 covers the insulating material 411 and the one end portion 901 of the base material 90 on the side of the insulating material 411. The base material 952 covers the insulating material 412 and the other end portion 902 of the base material 90 on the side of the insulating material 412.

It should be noted that in a case of conveying the base material 95 divided into the two parts as such, the wind-off roller 45 in the vacuum treatment apparatus 1 may be constituted by an integrated wind-off roller that simultaneously pays out the base material 951 and the base material 952 or may be constituted by a pair of wind-off rollers that independently pays out each of the base material 951 and the base material 952. When the wind-off roller 45 is constituted by a pair of wind-off rollers, the pair of wind-off rollers is arranged in parallel in the direction of the center axis 40c of the main roller 40. Similarly, the wind roller 46 may be constituted by an integrated wind roller that simultaneously winds the base material 951 and the base material 952 or may be constituted by a pair of wind rollers that independently winds each of the base material 951 and the base material 952. When the wind roller 46 is constituted by a pair of wind rollers, the pair of wind rollers is arranged in parallel in the direction of the center axis 40c of the main roller 40.

As shown in FIG. 2(a), at the position of the long dashed short dashed line C1, the vapor flow 21 is deposited on the base material 90 uncovered with the base material 95 and the base material 95 (base materials 951 and 952). Accordingly, a film 91 including the film deposition material from the deposition source 20 is formed on the base material 90. Moreover, a residual film 910 including the film deposition material is formed on the base material 95 (base materials 951 and 952). It should be noted that during film deposition, the film deposition material is formed on the film deposition surface 90d of the base material 90 while applying the bias potential to the main roller 40.

FIG. 2(b) schematically shows cross-sections of the respective base materials, the film, the insulating material, the residual film, and the main roller taken along the long dashed short dashed line C2 shown in FIG. 1.

At the position of the long dashed short dashed line C2, the base material 95 (base materials 951 and 952) and the residual film 910 are moved away from the insulating material 410 and the base material 90. After that, the base material 95 and the residual film 910 are wound by the wind roller 46.

On the other hand, the base material 90 with the film 91 formed thereon remains on a portion of the main roller 40, which is uncovered with the base material 95. After that, the base material 90 and the film 91 are moved away from the main roller 40 and are wound by the wind roller 42. This state is shown in FIG. 2(c). For example, FIG. 2(c) schematically shows cross-sections of the main roller and the insulating material taken along the long dashed short dashed line C3 shown in FIG. 1.

As shown in FIG. 2(c), the base material 90 and the film 91 are moved away from the main roller 40 and a part of the outer circumferential surface 403 of the main roller 40 is coated with the insulating material 410 (insulating materials 411 and 412). After that, the state in FIG. 2(a) is provided again, and then the operations shown in the order of FIG. 2(b) and FIG. 2(c) are repeated.

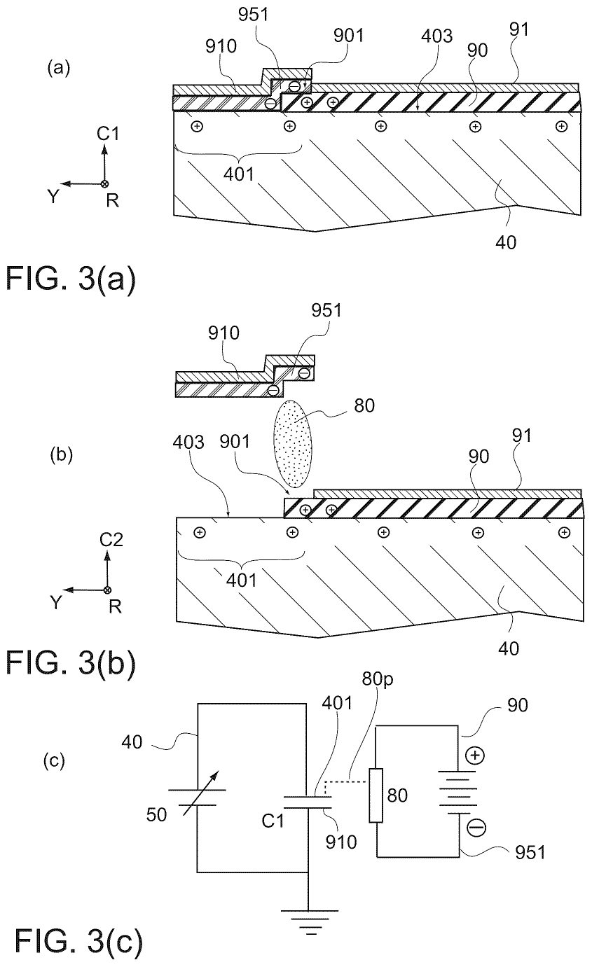

Actions of a vacuum treatment apparatus according to a comparative example will be described before describing actions of the vacuum treatment apparatus 1. FIG. 3(a) to FIG. 3(c) are diagrams describing the actions of the vacuum treatment apparatus according to the comparative example. FIG. 3(a) shows the comparative example corresponding to the position of the long dashed short dashed line C1 in FIG. 1 and FIG. 3(b) shows the comparative example corresponding to the position of the long dashed short dashed line C2 in FIG. 1. FIG. 3(c) shows an equivalent circuit showing the state in FIG. 3(b). FIG. 3(a) to FIG. 3(c) show actions on the side of the end portion 401 of the both end portions of the main roller 40. A phenomenon shown in FIG. 3(a) to FIG. 3(c) can also occur on the side of the end portion 402 of the main roller 40.

In the comparative example, the insulating material 410 (insulating materials 411 and 412) is not provided on the main roller 40. With such a configuration, the following phenomenon can occur.

For example, when the main roller 40 winds and conveys the base materials 90 and 95, the base materials 90 and 95 can be charged with static electricity due to a difference in charging series between the base material 90 and the base material 95 and friction between the base material 90 and the base material 95.

For example, FIG. 3(a) shows a state in which the end portion 901 of the base material 90 is charged to have a positive potential and the base material 951 is charged to have a negative potential as an example. It should be noted that the respective films are both at the ground potential because the film 91 formed on the base material 90 is wound by the wind roller 42 and the residual film 910 formed on the base material 951 is wound by the wind roller 46. Moreover, a positive potential is applied on the main roller 40 from the bias power source 50.

Keeping such a state, when the base material 951 is moved away from the main roller 40 as shown in FIG. 3(b), the degree of vacuum between the base material 951 and the end portion 901 of the base material 90 locally increases because the base material 951 is degassed, for example. In addition, an electric field is formed between the base material 951 and the end portion 901 of the base material 90 due to the static electricity charging the base material 951 and the static electricity charging the base material 90. Accordingly, discharge plasma 80 can be generated between the base material 951 and the end portion 901 of the base material 90. The discharge plasma 80 can be generated also when the end portion 901 of the base material 90 is charged to have a negative potential and the base material 951 is charged to have a positive potential.

When such discharge plasma 80 is generated near the portion where the outer circumferential surface 403 of the main roller 40 is exposed, electric charges in the discharge plasma 80 are attracted to the outer circumferential surface 403 of the main roller 40. As a result, an electrical path 80p is formed between the discharge plasma 80 and the outer circumferential surface 403 of the main roller 40 (FIG. 3(c)). That is, an electrical short-circuit occurs between the discharge plasma 80 and the main roller 40.

When such an electrical short-circuit occurs, the bias potential applied on the main roller 40 becomes unstable and the electrostatic adhesion force between the main roller 40 and the base materials 90 and 95 becomes unstable. Accordingly, the base materials 90 and 95 may be deviated on the outer circumferential surface 403 of the main roller 40 or the base materials 90 and 95 may be wrinkled during film deposition.

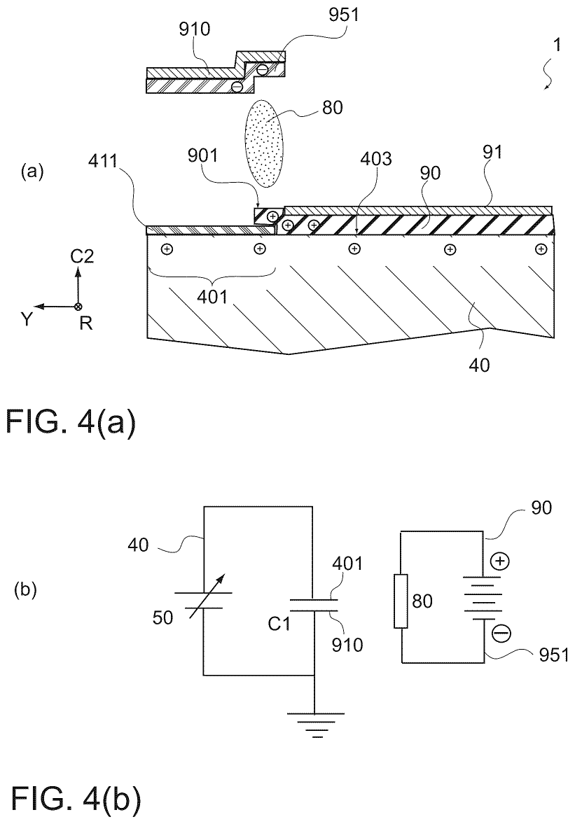

Next, actions of the vacuum treatment apparatus according to the present embodiment will be described. FIGS. 4(a) and 4(b) are diagrams describing the actions of the vacuum treatment apparatus according to the present embodiment. FIG. 4(a) shows an example corresponding to the position of the long dashed short dashed line C2 in FIG. 1. FIG. 4(b) shows an equivalent circuit showing the state in FIG. 4(a). FIGS. 4(a) and 4(b) show actions on the side of the end portion 401 of the both end portions of the main roller 40. A phenomenon shown in FIGS. 4(a) and 4(b) also occurs on the side of the end portion 402 of the main roller 40.

As shown in FIG. 4(a), in the present embodiment, the main roller 40 is coated with the insulating material 410 (insulating materials 411 and 412). Accordingly, as shown in FIG. 4(a), the electric charges in the discharge plasma 80 are shielded by the insulating material 411 even if the discharge plasma 80 is formed between the base material 951 and the end portion 901 of the base material 90. Accordingly, the electrical path 80p is not formed (FIG. 4(b)) and electric charges in the discharge plasma 80 are inhibited from reaching the outer circumferential surface 403 of the main roller 40.

Therefore, the bias potential applied on the main roller 40 is stable and the electrostatic adhesion force between the main roller 40 and the base materials 90 and 95 is stable. Accordingly, the base materials 90 and 95 are inhibited from being deviated on the outer circumferential surface 403 of the main roller 40 and the base materials 90 and 95 are inhibited from being wrinkled during film deposition.

Hereinabove, the embodiments of the present invention have been described, though the present invention is not limited to those embodiments and various modifications can be made as a matter of course. For example, the present embodiment also encompasses a configuration in which the entire region of the outer circumferential surface 403 of the main roller 40 is coated with the insulating material and similar actions and effects are provided also with this configuration. The respective embodiments are not limited to the aspects in which they are independently carried out and can be combined as long as it is technically possible.

What is claimed is:

1. A vacuum treatment apparatus, comprising:
a first wind-off roller that pays out a first base material having a film deposition surface and a non-film deposition surface opposite to the film deposition surface;
a first wind roller that winds the first base material;
a main roller that is provided between the first wind-off roller and the first wind roller in a direction in which the first base material is conveyed, has an outer circumferential surface that is held in contact with the non-film deposition surface, and winds and conveys the first base material, at least a part of the outer circumferential surface, which is uncovered with the first base material, being coated with an insulating material;
a deposition source that faces the outer circumferential surface of the main roller that is held in contact with the non-film deposition surface;
a second wind-off roller that pays out a second base material that is wound and conveyed by the main roller and covers a part of the film deposition surface of the first base material on the outer circumferential surface of the main roller;
a second wind roller that winds the second base material; and
a power source that applies a bias potential to the main roller.

2. The vacuum treatment apparatus according to claim 1, wherein
the main roller has both end portions coated with the insulating material.

3. The vacuum treatment apparatus according to claim 1, wherein
the second base material is wound and conveyed by the main roller while the second base material is held in contact with the insulating material on the outer circumferential surface of the main roller.

4. A vacuum treatment method, comprising:
obtaining a vacuum treatment apparatus that comprises:
a first wind-off roller that pays out a first base material having a film deposition surface and a non-film deposition surface opposite to the film deposition surface,
a first wind roller that winds the first base material,
a main roller that is provided between the first wind-off roller and the first wind roller in a direction in which the first base material is conveyed, has an outer circumferential surface that is held in contact with the non-film deposition surface, and winds and conveys the first base material, at least a part of the outer circumferential surface, which is uncovered with the first base material, being coated with an insulating material,
a deposition source that faces the outer circumferential surface of the main roller that is held in contact with the non-film deposition surface,
a second wind-off roller that pays out a second base material that is wound and conveyed by the main roller and covers a part of the film deposition surface of the first base material on the outer circumferential surface of the main roller, and
a second wind roller that winds the second base material; and
forming a film deposition material on the film deposition surface while applying a bias potential to the main roller.

5. The vacuum treatment method according to claim 4, further comprising coating both end portion of the main roller with the insulating material.

6. The vacuum treatment method according to claim 4, further comprising
winding and conveying the second base material by the main roller while the second base material is held in contact with the insulating material on the outer circumferential surface of the main roller.
